(19) United States
(12) Patent Application Publication
(10) Pub. No.: US 2004/0158982 A1
(43) Pub. Date: Aug. 19, 2004

(54) Wire press-contact method and method of attaching press-contact terminal to connector housing

(75) Inventor: Yasushi Saitoh, Nagoya-shi (JP)

Correspondence Address: OLIFF & BERRIDGE, PLC, P.O. BOX 19928, ALEXANDRIA, VA, 22320, US

(73) Assignees: AUTONETWORKS TECHNOLOGIES, LTD., Nagoya-shi (JP); SUMITOMO WIRING SYSTEMS, LTD., Yokkaichi-shi (JP); SUMITOMO ELECTRIC INDUSTRIES, LTD., Osaka-shi (JP)

(21) Appl. No.: 10/782,798

(22) Filed: Feb. 23, 2004

Related U.S. Application Data
(62) Division of application No. 09/986,704, filed on Nov. 9, 2001.

(30) Foreign Application Priority Data
Nov. 15, 2000 (JP) 2000-348104

(51) Int. Cl. H05K 1/00; H01R 12/00

(52) U.S. Cl. 29/884; 29/857; 29/858; 29/876

(57) ABSTRACT

In a wire press-contact method, press-contact terminals 100 are set in terminal fitting groove portions 4 provided in a receiving jig 1, each of which permits the entire longitudinal length of the press-contact terminal 100 to be fitted thereinto, in a fitted state. After set therein, a wire 103 is placed correspondingly to a position located above a press-contact blade 102 of each of the press-contact terminals 100. Thereafter, the wire 103 is press-fitted into a corresponding one of the press-contact blades 102 by driving a press-contact head 7, which is enabled to be ascendably and descendably driven, in such a way as to ascend and descend.

### BACKGROUND OF THE INVENTION

This is a divisional application of U.S. application Ser. No. 09/986,704 filed on Nov. 9, 2001.

1. Field of the Invention

The present invention relates to a wire press-contact method for press-fitting a wire having a coating layer into a press-contact blade of a press-contact terminal to thereby connect the wire and the press-contact blade to each other, and also relates to a method of attaching a press-contact terminal to a connector housing.

2. Description of the Related Art

For example, as shown in FIG. 4, a press-contact terminal 100 has a structure that comprises a terminal connection portion 101, to which another terminal corresponding to a longitudinal end portion thereof is connected, and that also comprises a press-contact blade 102, which is provided in a longitudinally middle portion thereof, and a wire holding portion 104 provided in the other end portion thereof and used for embracing a wire 103.

Further, the press-contact terminal 100 is configured so that when the wire 103 is made to correspond to an upper position of the press-contact blade 102 and placed along the longitudinal direction of the press-contact terminal 100 and pushed against the press-contact blade 102 by a press-contact head attached to an applicator and press-fitted into the press-contact blade, a coating layer of the wire 103 is cut into by the press-contact blade 102, an inner electrical conductor is exposed to thereby obtain a connection state in which an edge portion of the press-contact blade 102 and the electrical conductor of the wire 103 are press-contacted with and electrically conducted to each other. Moreover, the press-contact terminal 100 is constructed so that a wire holding portion 104 is bent toward the side of the surface of the coating layer and thus embraces and holds an end portion of the wire 103, as shown in FIG. 5.

Furthermore, in a connector using such a kind of a press-contact terminal 100, for instance, the press-contact terminals 100 held in a predetermined posture are respectively set in such a way as to be fitted into a plurality of groove-like terminal attaching portion 111 provided in a first housing 110 in a parallel manner, as shown in FIG. 6. Then, wires 103 are respectively and serially placed at positions located above the press-contact blades 102 of the press-contact terminals 100. Moreover, the wires 103 placed thereat are respectively and sequentially press-fitted into the press-contact blades 102.

On the other hand, similarly, the press-contact terminals 100 held in a predetermined posture are respectively set in such a way as to be fitted into a plurality of groove-like terminal attaching portions 116 provided in a second connector housing 115 in a parallel manner. Wires 103 are respectively and serially placed at positions located above the press-contact blades 102 of the press-contact terminals 100. Moreover, the wires 103 placed thereat are respectively and sequentially pressed into the press-contact blades 102.

Further, as shown in FIG. 8, a cover body 112 of the first press-contacted connector housing 110 is fitted to and locked by the press-contact terminals 100 in such a way as to cover therewith. Subsequently, a connector is assembled by combining the first connector housing 110 and the second connector housing 115 with each other in a superposed manner in such a way as to cover each of the press-contact terminals 100 of the second press-contacted connector housing 115.

Meanwhile, in the case that let H, Ha, and Hb denote a press-contact height of the wire 103, which is press-contacted with the press-contact blade 102, with respect thereto, a minimum height of the conductor portion 103a of the press-fitted wire 103, and a maximum height thereof, respectively, and that H=(Ha+Hb)/2, there is a relationship between an electrical connection characteristic and the press-contact height H of the wire 103, which is illustrated in FIG. 10. Incidentally, in this figure, reference character HL designates a lower limit of the press-contact height H.

Further, there is the necessity for establishing a set value (or design value) H₀ of the press-contact height H, which is set at a manufacturing process of manufacturing a connector by press-contacting the wire 103 with the press-contact terminal 100, in such a manner that a manufacturing range including positive and negative tolerances α is included a stability range of contact resistance, as illustrated in FIG. 10.

Furthermore, in an actual manufacturing process, process capability Cₚₖ is generally evaluated. Then, the press-contact height is set and a production control operation is performed so as to manufacture products so that the distribution of variation in press-contact height among the products is within the tolerance α, as illustrated in FIG. 11. Furthermore, it is usually requested that this process capability Cₚₖ meets the following inequality: Cₚₖ>1.33.

However, as the miniaturization of connectors and various kinds of devices advances, the miniaturization of the press-contact terminal 100 has advanced. Consequently, as compared with the stability range of contact resistance the case of a relation curve A of the press-contact terminal 100, which is represented by a solid curve shown in FIG. 12, that of contact resistance in the case of a relation curve B of a smaller press-contact terminal 100, which is represented by an imaginary curve, tends to become narrower. Thus, the stability range of contact resistance in the case of the relation curve B of the smaller press-contact terminal 100 tends to become narrower than a manufacturable range.

Further, as the manufacturable range narrows, the range of settable tolerance a becomes narrow. Thus, it has become gradually difficult for the process capability Cₚₖ to satisfy a value that has hitherto been ordinary.

That is, as illustrated in FIG. 13, in the case corresponding to a distribution curve A1 of the press-contact terminal 100, which is indicated by a solid curve, there is a margin in the process capability Cₚₖ. In contrast, in the case corresponding to a distribution curve B1 of the smaller press-contact terminal 100, which is indicated by an imaginary curve, the value of the conventional process capability Cₚₖ becomes unsatisfied. Further, to solve this problem, it is necessary to reduce the variation among products which is caused when manufactured, to that in the case corresponding to a distribution curve B2, which is indicated by a one-dot chain curve. Therefore, it is necessary to control the press-contact height H at the time of manufacturing connectors with high precision.

On the other hand, the aforementioned wire press-contact method is to press-fit the wires 103 into the press-contact terminals 100 in a state in which the press-contact terminals 100 are attached to the terminal attaching portions 111 and 116 of the first connector housing 110 and the second connector housing 115. Thus, the molding tolerances (including warp and deflection) of the resin-molded connector housings 110 and 115 largely affect the press-contact height H as a factor of the variation in the press-contact height H.

### SUMMARY OF THE INVENTION

Accordingly, in view of the aforementioned problems of conventional method, an object of the invention is to provide a wire press-contact method enabled to control the press-contact height with good accuracy and to provide a method of attaching a press-contact terminal to a connector housing.

To achieve the foregoing object, according to the invention, there is provided a wire press-contact method for connecting wires and press-contact blades of press-contact terminals to each other by press-fitting the wires into the press-contact blades of the press-contact terminals. This wire press-contact method comprises the steps of setting press-contact terminals in terminal fitting groove portions provided in a receiving jig, each of which permits the entire longitudinal length of a corresponding one of the press-contact terminals to be fitted thereinto, in a fitted state, and of placing, after setting the press-contact terminals therein, a wire correspondingly to a position located above a press-contact blade of each of the press-contact terminals, and of thereafter press-fitting the wire into a corresponding one of the press-contact blades by driving a press-contact head, which is enabled to be ascendably and descendably driven, so as to ascend and descend.

Further, this method may be adapted so that a plurality of the terminal fitting groove portions are placed in a parallel state in the receiving jig, that after press-contact terminals are respectively set in a fitted state into said terminal fitting groove portions, wires are serially placed corresponding to positions located above the press-contact blades, and that the placed wires are respectively and sequentially press-fitted into the press-contact blades by driving a press-contact head, which is enabled to be ascendably and descendably driven, in such a way as to ascend and descend.

Furthermore, a method of attaching a press-contact terminal to a connector housing may be provided as a method adapted so that each of the press-contact terminals respectively set in the terminal fitting groove portions, into each of which the wire is press-fitted by performing the aforementioned wire press-contact method, is pushed out along the longitudinal direction thereof to thereby to be attached in a corresponding one of terminal attaching holes of the connector housing.

### BRIEF DESCRIPTION OF THE DRAWINGS

FIG. 1 is a view illustrating a process according to an embodiment of the invention;

FIG. 2 is a view illustrating the process according to the embodiment of the invention;

FIG. 3 is a view illustrating the process according to the embodiment of the invention;

FIG. 4 is a view illustrating a process of press-contacting a wire to a press-contact terminal.

FIG. 5 is a perspective view illustrating a state in which the wire is press-contacted with the press-contact terminal.

FIG. 6 is a view illustrating a conventional process.

FIG. 7 is a view illustrating the conventional process.

FIG. 8 is a view illustrating the conventional process.

FIG. 9 is a view illustrating a press-contact height.

FIG. 10 is a graph illustrating the relation between a press-contact height and contact resistance.

FIG. 11 is a graph illustrating the relation between a press-contact height and a frequency.

FIG. 12 is a graph illustrating the relation between a press-contact height and contact resistance.

FIG. 13 is a graph illustrating the relation between a press-contact height and a frequency.

### DETAILED DESCRIPTION OF THE PREFERRED EMBODIMENTS

Hereinafter, an embodiment of the invention is described with reference to the accompanying drawings. In FIG. 1, reference numeral 1 designates a receiving jig formed by processing metal. The receiving jig 1 has a rectangular plate-like substrate portion 2, and a plurality of sidewall bodies 3 provided on the top surface side of the substrate portion 2 at predetermined intervals in a parallel state in such a way as to protrude therefrom. Further, a terminal fitting groove portion 4 is constructed in such a way as to be able to removably fit the press-contact terminal 100 between adjacent ones of the sidewall bodies 3.

Further, each of the terminal fitting groove portions 4 arranged in this parallel state is configured in such a manner as to be slightly longer than the length in the longitudinal direction of the press-contact terminal 100, so that the entire longitudinal length of the press-contact 100 can be fitted thereinto.

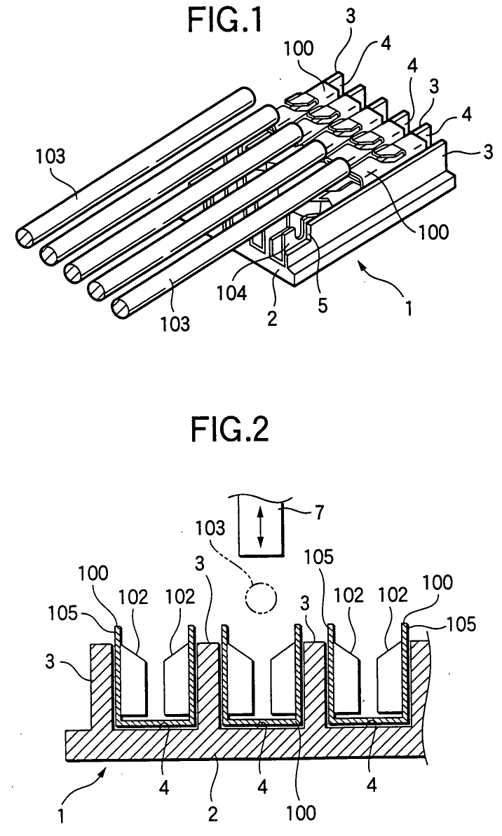

Furthermore, a rectangular cutout 5 is formed in an upper portion at the side of an end part in the direction of length of each of the sidewall bodies 3. A wire holding portion 104 is constructed in such a way as to be able to be bent in a state in which each of the press-contact terminals 100 is fitted in a corresponding one of the terminal fitting groove portions 4. Moreover, as illustrated in FIG. 2, the height of each of the sidewall bodies 3 is set so that wire guide walls 105, which are formed on both transversal sides of each of the press-contact terminals 100 by cutting up the press-contact blades 102, upwardly project from the top surface of each of the sidewall bodies 3 in a state in which each of the press-contact terminals 100 is fitted in a corresponding one of the terminal fitting groove portion 4.

Further, as shown in FIGS. 1 and 2, when the wires 103 are respectively press-contacted with the press-contact terminals 100, the press-contact terminals 100 are respectively fitted to the terminal fitting grooves 4 of the receiving jig 1. At that time, each of the wire holding portions 104 of the press-contact terminals 100 are set in such a way as to be placed at the side of a corresponding one of the cutout portions 5 of the sidewall bodies 3.

Subsequently, the receiving jig 1, in which the press-contact terminals 100 are set, is set at a predetermined position in an applicator mounted in a press apparatus. Further, the wire 103 is placed correspondingly to a position located above the press-contact blade 102 and the wire holding portions 104 of each of the press-contact terminals 100 set in the receiving jig 1 corresponding to a position located under a press-contact head 7 enabled to be ascendably and descendably driven. When the wire 103 is pushed against and press-fitted into the press-contact blade 102 by driving the press-contact head 7 in such a way as to ascend and descend in such a state, a coating layer of the wire 103 is cut into by the press-contact blade 102, similarly as in the aforementioned case. Thus, this jig obtains a state in which an edge portion of the press-contact blade 102 and a conductor portion of the wire 103 are press-contacted with and electrically conducted to each other. Moreover, each of the wire holding portions 104 is bent toward the surface of the surface of the coating layer of the wire 103 by a press-attaching head (not shown) to be interlocked with the press-contact head 7 and driven in such a way as to ascend and descend. Thus, the wire holding portions 104 embrace and hold an end portion of each of the wire 103.

Upon completion of the process of press-contacting the wire 103 with the press-contact terminal 100 corresponding to a position under the press-contact head 7, the receiving jig 1 is moved in a sideward direction by a predetermined distance so that the press-contact blade 102 of another of the press-contact terminals 110, which is not press-contacted yet, is moved to a position under the press-contact head 7. Then, similarly, the wire 103 is placed and the press-contact head 7 is driven in such a way as to ascend and descend, so that the wire 103 is press-contacted with the press-contact blade 102, and held by the wire holding portion 104.

From then on, the wires 103 are sequentially press-contacted with the press-contact blades 102 of the press-contact terminals 100 in a similar way.

Incidentally, the method of press-contacting the wire 103 with each of the press-contact terminals 100 has been described above. However, when the jig has a structure in which a plurality of press-contact heads 7, the number of which corresponds to that of the press-contact terminals 100, the workability is enhanced by adapting the method so that the wires 103 are placed onto the press-contact terminals 100, and that the wires 103 are simultaneously and respectively press-fitted thereinto.

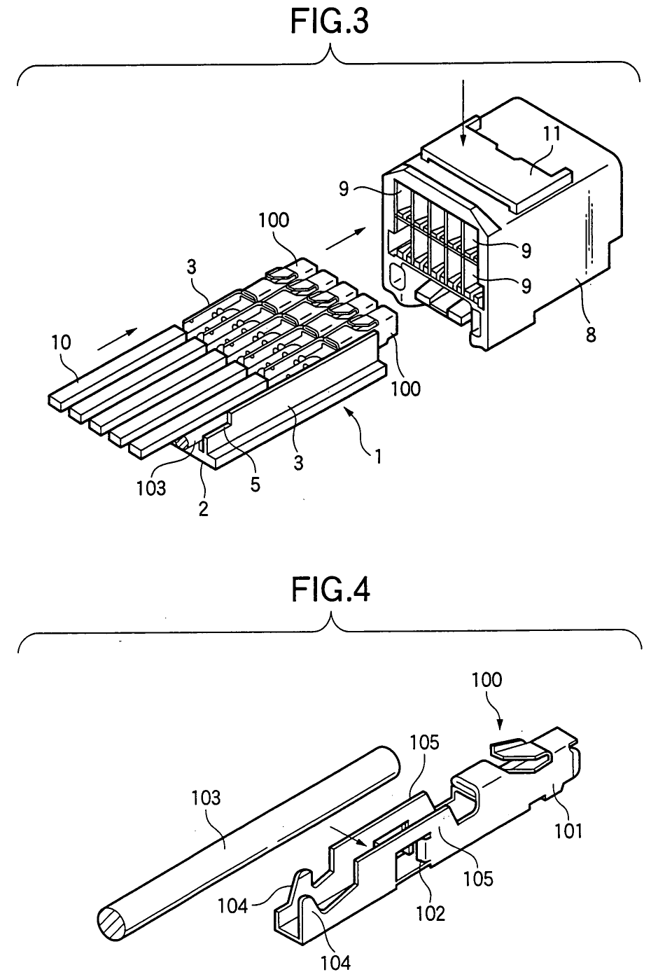

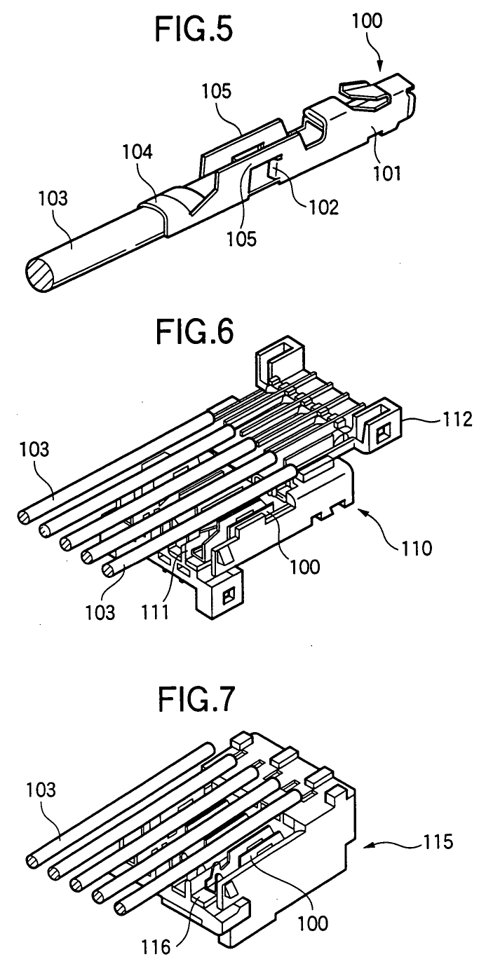

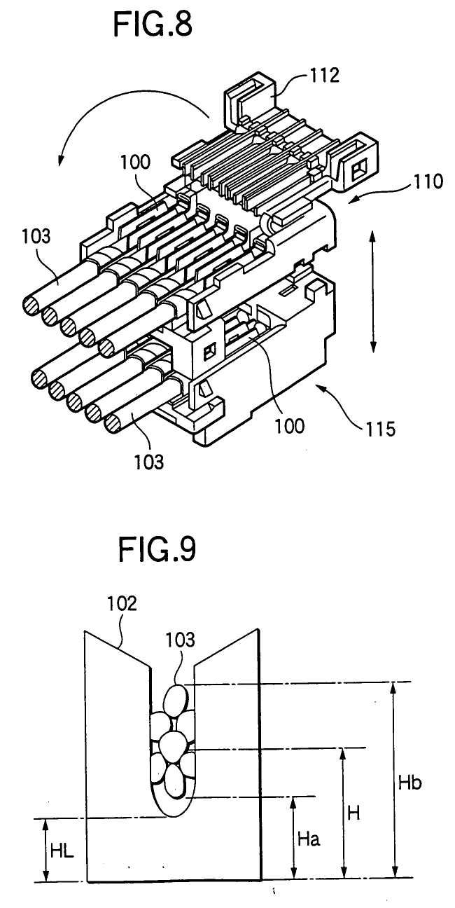

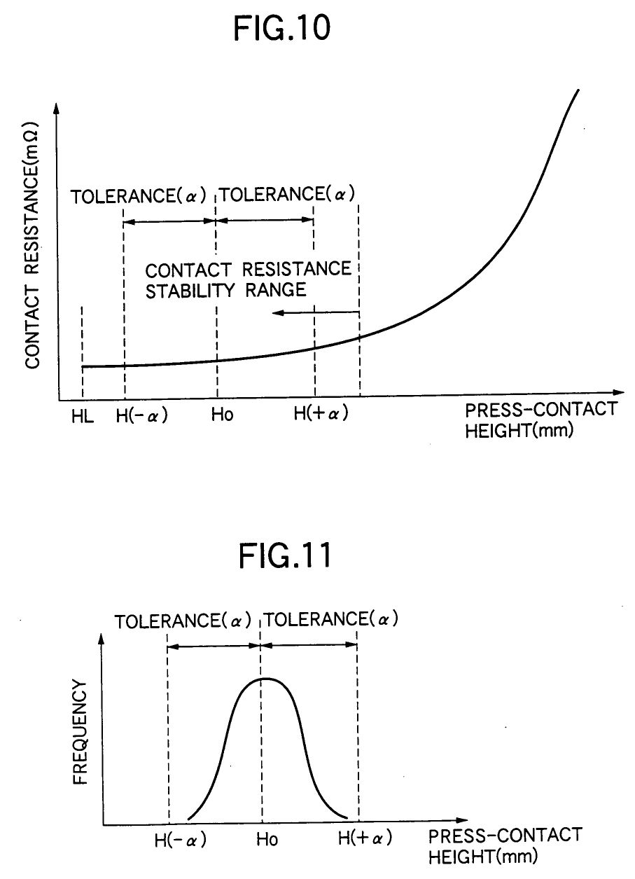

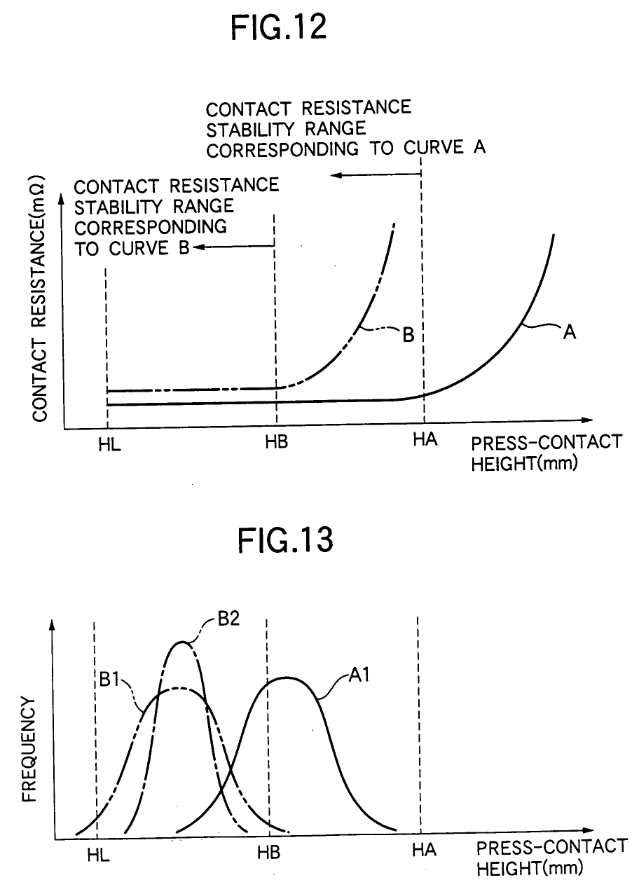

In the case that the press-contact terminals 100, with each of which the press-contact blade 102 and the wire 103 are press-contacted, are attached in the terminal attaching holes 9 provided in a connector housing 8a of a connector 8 formed from a resin, as shown in FIG. 3, when the press-contact terminals 100 are respectively inserted into and attached in the terminal attaching holes 9 of the connector housing 8a placed at the opposite position by pushing out the press-contact terminals 100 along the longitudinal direction thereof in a state in which the press-contact terminals 100 are set in the terminal fitting groove portions 4 of the receiving jig 1. Further, when the press-contact terminals 100 are respectively attached in the terminal fitting holes 9, the press-contact terminals 100 are held in a slip-off preventing manner by inserting a retainer 11 into the connector housing 8a.

It is sufficient for pushing out the press-contact terminals 100 from the terminal fitting groove portions 4 by pushing the pushing jig 10 to perform a pushing operation on an upper portion of each of the wire guide walls 105 upwardly projecting from the sidewall bodies 3.

Further, the operation of pushing out the press-contact terminals 100 may be performed on each of the terminals 100. Alternatively, the operation of pushing out the press-contact terminals 100 may be performed collectively and simultaneously on the terminals 100.

As described above, the wire press-contact method according to this embodiment uses the receiving jig 1 without using the connector housings 110 and 115 formed from a resin having a large molding tolerance, which are used in the conventional connector, when the wires 103 are press-contacted with the press-contact blades 102 of the press-contact terminals 100. Thus, the press-contact height H can be controlled with good accuracy. Moreover, a stable and good press-contact operation can be performed on small press-contact terminals 100.

Furthermore, the entire longitudinal length of each of the press-contact terminals 100 is enabled to be fitted into the corresponding terminal fitting groove portion 4 of the receiving jig 1. Thus, when the press-contacting is performed by using the press-contact head 7, the posture of each of the press-contact terminals 100 is stably held. Even from this viewpoint, the control operation can be performed on the press-contact height with good accuracy. Moreover, there is no need for holding the posture of each of the press-contact terminals by the press-contact head 7. Consequently, the structure of each of the press-contact head 7 can be simplified.

Further, the method of attaching the press-contact terminals 100 in the connector housing 8a is to perform an operation of pushing the press-contact terminals 100, which are set in the terminal fitting groove portions 4 of the receiving jig 1, into the groove portions by using the pushing jig 10 upon completion of performing the press-contacting process on the press-contact terminals 100 of the receiving jig 1. Thus, the workability is good.

Furthermore, there is no necessity for press-contacting the terminals on the connector housings 110 and 115, on which the press-contacting thereof is performed in the conventional case. Thus, it is unnecessary to employ a split structure as the structure of the connector housing. Consequently, the structure of the connector housing 8a can be simplified. Moreover, an assembling process is simplified. Even from this viewpoint, the workability is enhanced still more.

Incidentally, although the foregoing description of the embodiment discloses the receiving jig 1 having five terminal fitting groove portions 4, the number of which is determined according to that of the terminal attaching holes 9 provided in parallel with one another in the connector housing 8a, the number of the terminal fitting groove portions 4 is not limited to that in the case of the embodiment.

Further, although the foregoing description of the embodiment describes the structure in which two stages of the terminal attaching holes 9 of the connector housing 8a are disposed, the terminal attaching holes 9 may be placed on a single stage. The shape and structure of the terminal attaching holes 9 are not limited to those of the embodiment.

As described above, the wire press-contact method of the invention is to place the wires correspondingly to positions located above the press-contact blades after the press-contact terminals are set in the terminal fitting groove portions provided in the receiving jig into which the entire longitudinal length of each of the press-contact terminals can be fitted, and to press-fit the wires into the press-contact blades by driving the press-contact head, which is enabled to be ascendably and descendably driven, to ascend and descend. Additionally, the wire press-contact method of the invention is to use the receiving jig when the wires are press-contacted with the press-contact blades of the press-contact terminals. Thus, the wire press-contact method of the invention has an advantage in that the press-contact height can be controlled with good precision.

Furthermore, because the entire longitudinal length of the press-contact terminals are fitted in the terminal fitting groove portions of the receiving jig, the posture of each of the press-contact terminals is stably held when the press-contacting is performed by using the press-contact head. Thus, the wire press-contact method of the invention has another advantage in that even from this viewpoint, the control operation can be performed with good accuracy.

Moreover, the method of the invention, according to which a plurality of terminal fitting groove portions are placed in the receiving jig in a parallel manner, and to which the wires are serially placed corresponding to the positions located above the press-contact blades after the press-contact terminals are set in the terminal fitting groove portions in a fitted state, and to which the placed wires are sequentially press-fitted into the press-contact blade by performing ascent and descent driving operations of the press-contact head enabled to be ascendably and descendably driven, has advantages in that press-contacting operations are sequentially performed on the wires, and that this method excels in the workability.

Furthermore the method of the invention, according to which the press-contact terminals set in the terminal fitting groove portions are attached in the terminal attaching holes of the connector housing by pushing out the press-contact terminals in the longitudinal direction thereof by means of the pushing jig during the wires are press-fitted thereto, has advantages in that upon completion of the press-contact process, an operation of pushing the press-contact terminals having been set in the terminal fitting groove portions into the terminal attaching holes can be performed by using the pushing jig, that this method excels in the workability, and that the structure of the connector housing can be simplified.

What is claimed is:

1. A method of attaching a press-contact terminal to a connector housing, said method comprising the steps of:
setting press-contact terminals in terminal fitting groove portions provided in a receiving jig, each of which permits an entire longitudinal length of a corresponding one of said press-contact terminals to be fitted thereinto, in a fitted state;
press-fitting a wire into a corresponding one of said press-contact blades by driving a press-contact head, which is enabled to be ascendably and descendably driven, in such a way as to ascend and descend; and
pushing said press-contact terminals out along a longitudinal direction thereof to thereby be attached in a corresponding one of terminal attaching holes of said connector housing.

2. The method according to claim 1, wherein a plurality of said terminal fitting groove portions are placed in a parallel state in said receiving jig, wherein after press-contact terminals are respectively set in a fitted state into said terminal fitting groove portions, wires are serially placed corresponding to positions located above said press-contact blades, and wherein said placed wires are respectively and sequentially press-fitted into said press-contact blades by driving said press-contact head.
